(19) United States
(12) Patent Application Publication
(10) Pub. No.: US 2026/0290454 A1
(43) Pub. Date: Sep. 24, 2026

(54) METHOD FOR DRIVING SEMICONDUCTOR DEVICE AND SEMICONDUCTOR DEVICE

(71) Applicant: Nuvoton Technology Corporation Japan, Kyoto (JP)

(72) Inventors: Shunsaku MURAOKA, Kyoto (JP); Masahiro MORIMOTO, Kyoto (JP)

(21) Appl. No.: 19/670,146

(22) Filed: May 7, 2026

Related U.S. Application Data
(63) Continuation of application No. PCT/JP2024/042084, filed on Nov. 28, 2024.

(30) Foreign Application Priority Data
Dec. 1, 2023 (JP) 2023-203547

(51) Int. Cl. G11C 13/00

(52) U.S. Cl. CPC G11C 13/0069

(57) ABSTRACT

A method for driving a semiconductor device includes: setting a lower limit of a target resistance value of a nonvolatile resistive switching element; measuring a resistance value of the nonvolatile resistive switching element; determining whether the resistance value measured is below the lower limit of the target resistance value; and applying, when it is determined that the resistance value measured is below the lower limit of the target resistance value, a second high-resistance-setting voltage pulse and a first low-resistance-setting voltage pulse following the second high-resistance-setting voltage pulse to the nonvolatile resistive switching element. The second high-resistance-setting voltage pulse has second energy greater than first energy corresponding to a single application of the first high-resistance-setting voltage pulse, and applies a positive electric potential to a second electrode with respect to a first electrode.

### CROSS REFERENCE TO RELATED APPLICATIONS

This is a continuation application of PCT International Patent Application No. PCT/JP2024/042084 filed on Nov. 28, 2024, designating the United States of America, which is based on and claims priority of Japanese Patent Application No. 2023-203547 filed on Dec. 1, 2023. The entire disclosures of the above-identified applications, including the specifications, drawings and claims are incorporated herein by reference in their entirety.

### FIELD

The present disclosure relates to a method for driving a semiconductor device and a semiconductor device, and particularly to a driving method in which a target resistance value is written to a nonvolatile resistive switching element.

### BACKGROUND

Conventionally, methods have been proposed for driving a nonvolatile resistive switching element that holds, as a resistance value (may also referred to as a conductance value as the reciprocal of the resistance value), a weight coefficient (hereinafter, also simply referred to as a “weight”) that takes an analog, continuous value used for neural networks and the like (for example, Patent Literature (PTL) 1).

According to PTL 1, by performing forming on a nonvolatile resistive switching element and thereby controlling the area of a filament formed in a resistance change layer included in the nonvolatile resistive switching element, a weight coefficient taking an analog, continuous value is written to the nonvolatile resistive switching element as a resistance value. Here, the term forming refers to initial processing performed on a manufactured nonvolatile resistive switching element in which a relatively large voltage is applied to the nonvolatile resistive switching element, thereby causing the nonvolatile resistive switching element to transition to a state in which the nonvolatile resistive switching element can be reversibly switched between a high-resistance state and a low-resistance state. Moreover, a filament refers to a localized region through which current flows in a nonvolatile resistive switching element.

As compared to conventional write methods, the above-described technique disclosed by PTL 1 reduces variation in initially-written resistance values, fluctuation in readout resistance values, and retention properties. Here, the phrase variation in the initially-written resistance values refers to variation in the written resistance values obtained when a target resistance value is repeatedly written, and the phrase fluctuation in readout resistance values refers to changes in resistance values obtained when the written resistance value is repeatedly read. In addition, the term retention properties refers to the ability to retain written resistance values over time.

### CITATION LIST

### Patent Literature

PTL 1: International Publication No. 2021/149780

### SUMMARY

### Technical Problem

However, while the technique disclosed by PTL 1 can increase a filament area (i.e., a reduction in the resistance value) in a nonvolatile resistive switching element by performing forming on the nonvolatile resistive switching element, it is difficult to reduce the filament area (i.e., an increase in the resistance value). Note that in the present specification, a filament area or a filament size indicates a filament area or a filament size in a plan view of a resistance change layer.

From the above, the technique disclosed by PTL 1 can be applied to, as application of nonvolatile resistive switching elements to machine learning models, inference-purpose machine learning models that require a weight coefficient to be written only once; however, there is a problem in that the technique is not applicable to learning-purpose machine learning models that require a weight coefficient to be repeatedly written while changing the weight coefficient.

In view of the above, the present disclosure provides a method for driving a semiconductor device and a semiconductor device which are capable of, for a nonvolatile resistive switching element, (i) as compared to conventional write methods, reducing variation in initially-written resistance values, fluctuation in readout resistance values, and retention degradation, and (ii) unlike the technique disclosed by PTL 1, changing, in an analog manner, the resistance value toward both higher- and lower-resistance states.

### Solution to Problem

Given the foregoing, a method for driving a semiconductor device according to one aspect of the present disclosure is a method for driving a semiconductor including a nonvolatile resistive switching element, the semiconductor device applying voltage pulses to the nonvolatile resistive switching element to continuously and reversibly change a resistance value of the nonvolatile resistive switching element, the nonvolatile resistive switching element including: a first electrode; a second electrode; and a resistance change layer interposed between the first electrode and the second electrode and having a resistance value that continuously changes, the nonvolatile resistive switching element having a property of transitioning to a low-resistance state when a first low-resistance-setting voltage pulse is applied once and transitioning to a high -resistance state when a first high-resistance-setting voltage pulse is applied once, the first low-resistance-setting voltage pulse applying a negative electric potential to the second electrode with respect to the first electrode, the high-resistance state having a resistance value higher than a resistance value in the low-resistance state, the first high-resistance-setting voltage pulse applying a positive electric potential to the second electrode with respect to the first electrode, the method for driving the semiconductor device includes: setting a lower limit of a target resistance value of the nonvolatile resistive switching element; measuring the resistance value of the nonvolatile resistive switching element; determining whether the resistance value measured is below the lower limit of the target resistance value; and applying, when it is determined that the resistance value measured is below the lower limit of the target resistance value, a second high-resistance-setting voltage pulse and the first low-resistance-setting voltage pulse following the second high-resistance-setting voltage pulse to the nonvolatile resistive switching element, the second high-resistance-setting voltage pulse having second energy greater than first energy corresponding to a single application of the first high-resistance-setting voltage pulse, and applying a positive electric potential to the second electrode with respect to the first electrode.

Given the foregoing, a semiconductor device according to one aspect of the present disclosure includes: a nonvolatile resistive switching element that includes: a first electrode; a second electrode; and a resistance change layer interposed between the first electrode and the second electrode and having a resistance value that continuously and reversibly changes; and a driving circuit that drives the nonvolatile resistive switching element. The nonvolatile resistive switching element has a property of transitioning to a low-resistance state when a first low-resistance-setting voltage pulse is applied once and transitioning to a high-resistance state when a first high-resistance-setting voltage pulse is applied once, the first low-resistance-setting voltage pulse applying a negative electric potential to the second electrode with respect to the first electrode, the high-resistance state having a resistance value higher than a resistance value in the low-resistance state, the first high-resistance-setting voltage pulse applying a positive electric potential to the second electrode with respect to the first electrode, and the driving circuit, when it is determined that the resistance value of the nonvolatile resistive switching element is below a lower limit of a target resistance value, applies a second high-resistance-setting voltage pulse and the first low-resistance-setting voltage pulse following the second high-resistance-setting voltage pulse to the nonvolatile resistive switching element, the second high-resistance-setting voltage pulse having second energy greater than first energy corresponding to a single application of the first high-resistance-setting voltage pulse, and applying a positive electric potential to the second electrode with respect to the first electrode.

### Advantageous Effects

The present disclosure provides a method for driving a semiconductor device and a semiconductor device which are capable of, for a nonvolatile resistive switching element, (i) as compared to conventional write methods, reducing variation in initially-written resistance values, fluctuation in readout resistance values, and retention degradation and (ii) unlike the technique disclosed by PTL 1, changing, in an analog manner, the resistance value toward both higher- and lower-resistance states.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1A is a diagram illustrating variation in conductance values obtained when a plurality of resistance values are written to a single resistive switching element in a conventional method of driving a nonvolatile resistive switching element.

FIG. 1B is a diagram illustrating changes in resistance values (fluctuation in conductance values) and results of retention degradation obtained when resistance value A, resistance value B, and resistance value C are particularly repeatedly read among the plurality of resistance values shown in FIG. 1A.

FIG. 2A is a diagram illustrating the method for driving a nonvolatile resistive switching element disclosed by PTL 1.

FIG. 2B is a diagram illustrating results of analyzing filament properties using experimental results obtained by the method for driving the nonvolatile resistive switching element disclosed by PTL 1 and shown in FIG. 2A.

FIG. 2C is a diagram illustrating a problem found in the technique disclosed by PTL 1.

FIG. 3 is a diagram illustrating reversible changes in filament area caused by a method for driving a semiconductor device according to the present disclosure.

FIG. 4 is a block diagram illustrating a configuration of a semiconductor device according to an embodiment.

FIG. 5A is a flowchart illustrating operation performed by the semiconductor device (i.e., a method for driving the semiconductor device) according to the embodiment.

FIG. 5B is a diagram illustrating an example of a distribution of a resistance value corresponding to a target weight.

FIG. 6A is a diagram illustrating voltage conditions used in the experiment conducted in accordance with the flowchart shown in FIG. 5A, in which the nonvolatile resistive switching element is changed from a low-resistance state toward a higher-resistance state to achieve a plurality of resistance states, together with voltage conditions according to a conventional technique.

FIG. 6B is a diagram illustrating the distribution of conductance values (after application of the low-resistance (LR)-setting voltages) obtained from a plurality of experiments of writing to the nonvolatile resistive switching element in cases A to E shown in FIG. 6A.

FIG. 6C is a diagram illustrating results of analyzing filament properties using the results of experiments of cases A to E shown in FIG. 6A.

FIG. 7 is a diagram illustrating the state of a filament in an intermediate-resistance state after an LR-setting voltage is applied to the nonvolatile resistive switching element in a multivalued storage mode according to the embodiment.

FIG. 8 is a flowchart illustrating operation performed by a semiconductor device (i.e., a method for driving the semiconductor device) according to a variation of the embodiment.

FIG. 9 is a diagram illustrating a filament-state change model of a filament in the nonvolatile resistive switching element for the driving methods according to the embodiment and conventional technique.

FIG. 10 is a block diagram illustrating a detailed configuration of the semiconductor device according to the embodiment.

### DESCRIPTION OF EMBODIMENTS

### Knowledge Obtained by the Present Inventors

Conventionally, methods for driving a nonvolatile resistive switching element that stores weight coefficients taking analog, continuous values as conductance values or resistance values show significant variation in the written conductance values. In particular, when intermediate-resistance values, i.e., resistance values (intermediate conductance values) between high-resistance values and low-resistance values, are stored, large conductance-value variation, large conductance-value fluctuation, and significant retention degradation occur, resulting in reduced reliability.

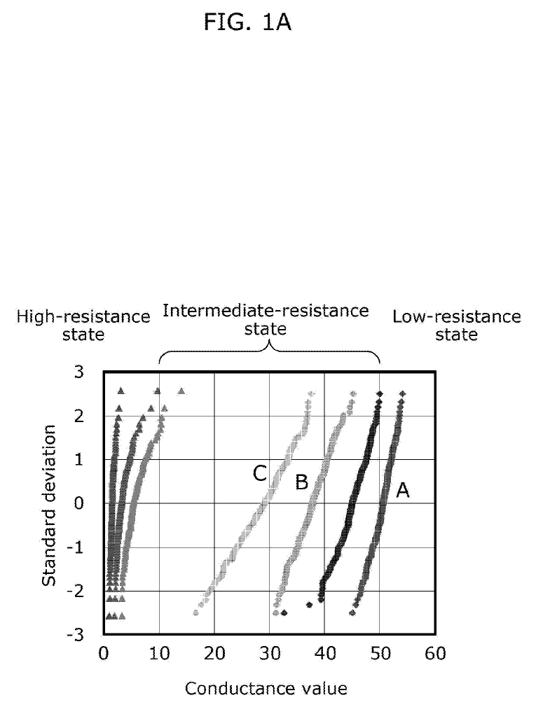

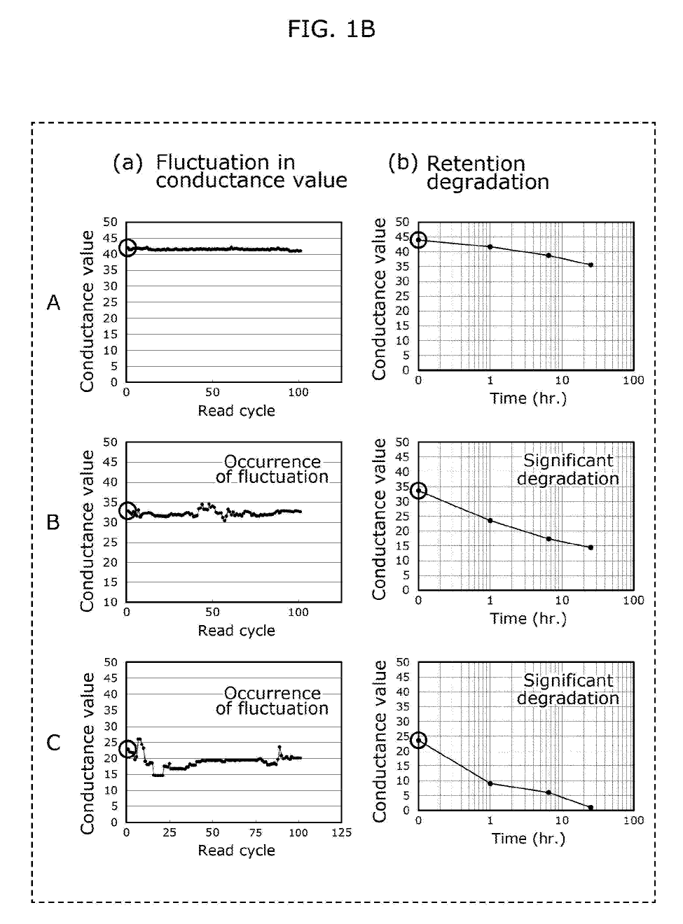

FIG. 1A is a diagram illustrating variation in conductance values obtained when a plurality of resistance values are written to a single resistive switching element in a conventional method of driving a nonvolatile resistive switching element. The diagram here shows the distribution of conductance values obtained by repeatedly writing, to achieve a plurality of resistance values, high-resistance values (“High-resistance state”), intermediate-resistance values (“Intermediate-resistance state”), and low-resistance values (“Low-resistance state”) to a single nonvolatile resistive switching element. The horizontal axis represents obtained conductance values, and the vertical axis represents standard deviations of the obtained conductance values.

Small variation is observed in the high-resistance state in which conductance values are small (see the leftmost-end portion in FIG. 1A) and in the low-resistance state in which conductance values are large (see the rightmost-end portion in FIG. 1A). However, large variation is observed in the intermediate-resistance state in which conductance values take intermediate values (the remaining portion other than both end portions). In particular, conductance values exhibit large variation in the intermediate‑resistance states B and C in which the conductance values are near the midpoint between the low- and high-conductance values.

FIG. 1B is a diagram illustrating changes in resistance values (fluctuation in conductance values) and results of retention degradation obtained when the plurality of resistance values A, B, and C written to the single nonvolatile resistive switching element shown in FIG. 1A are repeatedly read. More specifically, part (a) of FIG. 1B illustrates changes in conductance values (fluctuation in conductance values) observed when, among the plurality of resistance states, the conductance values written in low-resistance state A and intermediate-resistance states B and C are read. The horizontal axis represents read cycle and the vertical axis represents readout conductance values. Part (b) of FIG. 1B illustrates retention degradation of the conductance values written to low-resistance value A and intermediate-resistance values B and C among the plurality of resistance values. The horizontal axis represents elapsed time (hr) after the conductance values are written, and the vertical axis represents the conductance values.

As can be seen from FIG. 1B, intermediate‑resistance states B and C exhibit large fluctuation in the conductance values when the conductance values are repeatedly read, and also show significant retention degradation.

In view of the above, PTL 1 proposes, as a method for reducing such problems found in conventional driving methods (namely, large variation and large fluctuation in conductance values and significant retention degradation), a driving method in which conductance values taking analog, continuous values are written to a nonvolatile resistive switching element by performing forming on the nonvolatile resistive switching element and thereby controlling the filament area in the nonvolatile resistive switching element.

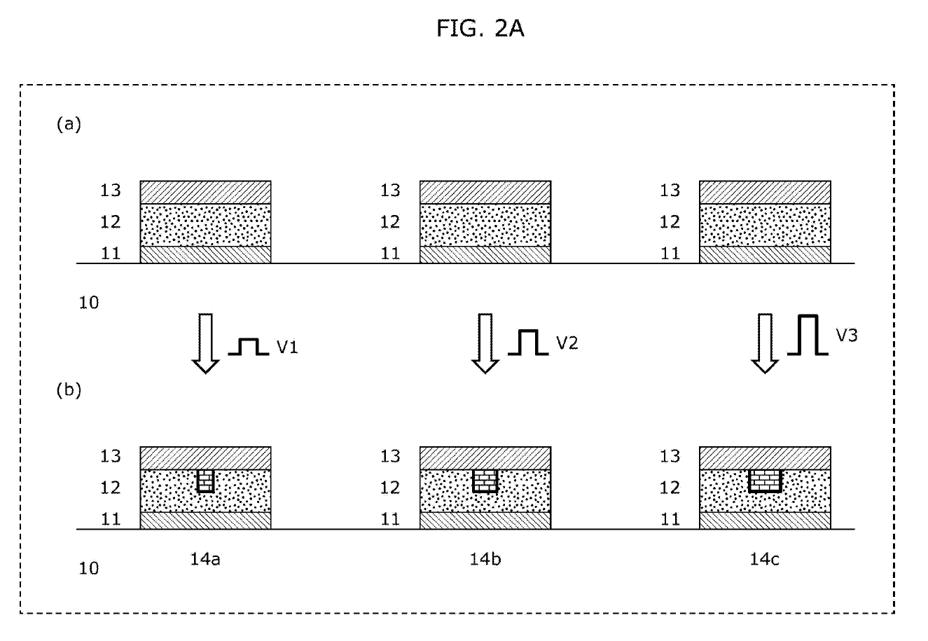

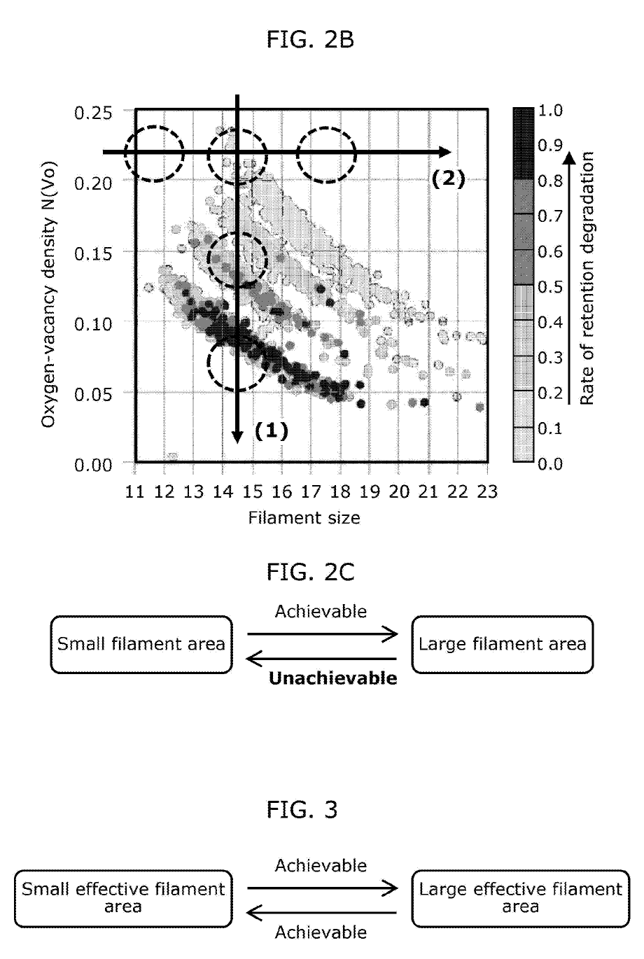

FIG. 2A is a diagram illustrating the method for driving nonvolatile resistive switching element 10 disclosed by PTL 1. The diagram shows the states of internal changes of nonvolatile resistive switching element 10 when forming is performed on nonvolatile resistive switching element 10 by applying three voltages V1 to V3 having different magnitudes and satisfying the relationship V1 < V2 < V3. Part (a) of FIG. 2A schematically illustrates a cross-sectional structure of nonvolatile resistive switching element 10 before forming is performed, and part (b) of FIG. 2A schematically illustrates a cross-sectional structure of nonvolatile resistive switching element 10 after the forming is performed.

As shown in parts (a) and (b) of FIG. 2A, nonvolatile resistive switching element 10 includes first electrode 11, second electrode 13, and resistance change layer 12 that is interposed between first electrode 11 and second electrode 13 and has the resistance value that continuously changes. As shown in part (b) of FIG. 2A, filaments 14a to 14c are formed in resistance change layer 12 by performing forming on nonvolatile resistive switching element 10. Each of filaments 14a to 14c is a local aggregation of oxygen vacancies in the metal oxide included in resistance change layer 12, and forms a path through which current flows.

Here, focusing on the filament area in a plan view of resistance change layer 12, it can be seen that forming performed using a larger voltage forms a filament having a larger area, which results in a lower resistance value.

FIG. 2B is a diagram illustrating results of analyzing filament properties using experimental results obtained by the method for driving nonvolatile resistive switching element 10 disclosed by PTL1 and shown in FIG. 2A. The diagram shows results of analyzing filament properties suitable for analog resistance values from experimental results on the filament properties and data retention properties of nonvolatile resistive switching element 10. The horizontal axis represents the filament size, the vertical axis represents oxygen-vacancy density in the filament, and the plot density denotes the data retention properties (lighter gradation indicating better data retention). Note that quantitative models of filament properties have been established using parameters such as a filament area and oxygen-vacancy density within the filament, and the filament properties have already been found to have a strong correlation with data retention properties (see PTL: Japanese Unexamined Patent Application Publication No. 2014-207046).

As shown by straight line (1) in FIG. 2B, conventional driving methods control analog resistance values to be written by controlling the oxygen-vacancy density within a filament while maintaining the filament size. In such methods, large conductance values, which can maintain high oxygen-vacancy densities, exhibit good data retention properties. Conversely, for small conductance values corresponding to low oxygen-vacancy densities, oxygen vacancies having poor data retention properties are used due to the low oxygen-vacancy densities, thereby causing variation in resistance values.

Whereas, as shown by straight line (2) in FIG. 2B, the technique disclosed by PTL 1 controls a filament size while maintaining a high oxygen-vacancy density, thereby forming a filament with superior data retention properties, namely, reduced variation in resistance values.

As described above, according to the technique disclosed by PTL 1, resistance values taking analog, continuous values are written to a nonvolatile resistive switching element by controlling the filament area included in the nonvolatile resistive switching element, and thereby reducing variation in written resistance values as compared to conventional driving methods.

However, the inventors of the present application have found the following problems in the technique disclosed by PTL 1.

FIG. 2C is a diagram illustrating a problem found in the technique disclosed by PTL 1. As shown by the present diagram, the technique disclosed by PTL 1 can increase the filament area (i.e., a reduction in the resistance value) in a nonvolatile resistive switching element by performing forming on the nonvolatile resistive switching element but has difficulty in reducing the filament area (i.e., an increase in the resistance value).

For this reason, the technique disclosed by PTL 1 can be applied to, as application to machine learning models including nonvolatile resistive switching elements, inference-purpose machine learning models that require a weight coefficient to be written only once; however, there is a problem in that the technique is not applicable to learning-purpose machine learning models that require a weight coefficient to be repeatedly written while changing the weight coefficient.

In view of the above, the inventors of the present application have conducted in-depth studies for implementation of a method for driving a semiconductor device and a semiconductor device (i.e., achievement of the disclosure of the present application) which are capable of, for a nonvolatile resistive switching element, (i) as compared to conventional write methods, reducing variation in initially-written resistance values, fluctuation in readout resistance values, and retention degradation, and (ii) unlike the technique disclosed by PTL 1, changing, in an analog manner, the resistance value toward both higher- and lower-resistance states.

As a result, the inventors devised a method for reversibly changing, in an analog manner, the effective filament area of a filament without significantly changing the oxygen vacancy density within the filament as shown in FIG. 3, by implementing a method for driving a semiconductor device or a semiconductor device having the following features. FIG. 3 is a diagram illustrating reversible changes in filament area caused by a method for driving a semiconductor device according to the present disclosure. Note that an effective filament area is not the outer area of the filament as defined by its contour, but an active area of a region that functions as a filament.

One aspect of the above-described method for driving a semiconductor device is a method for driving a semiconductor device including a nonvolatile resistive switching element. The semiconductor device applies voltage pulses to the nonvolatile resistive switching element to continuously and reversibly change a resistance value of the nonvolatile resistive switching element . The nonvolatile resistive switching element includes: a first electrode; a second electrode; and a resistance change layer interposed between the first electrode and the second electrode and having a resistance value that continuously changes. The nonvolatile resistive switching element has a property of transitioning to a low-resistance state when a first low-resistance-setting voltage pulse is applied once and transitioning to a high-resistance state when a first high-resistance-setting voltage pulse is applied once. The first low-resistance-setting voltage pulse applies a negative electric potential to the second electrode with respect to the first electrode. The high-resistance state has a resistance value higher than a resistance value in the low-resistance state. The first high-resistance-setting voltage pulse applies a positive electric potential to the second electrode with respect to the first electrode. The method for driving the semiconductor device includes: setting a lower limit of a target resistance value of the nonvolatile resistive switching element; measuring the resistance value of the nonvolatile resistive switching element; determining whether the resistance value measured is below the lower limit of the target resistance value; and applying, when it is determined that the resistance value measured is below the lower limit of the target resistance value, a second high-resistance-setting voltage pulse and the first low-resistance-setting voltage pulse following the second high-resistance-setting voltage pulse to the nonvolatile resistive switching element. The second high-resistance-setting voltage pulse has second energy greater than first energy corresponding to a single application of the first high-resistance-setting voltage pulse, and applies a positive electric potential to the second electrode with respect to the first electrode.

One aspect of the above-described semiconductor device includes: a nonvolatile resistive switching element that includes: a first electrode; a second electrode; and a resistance change layer interposed between the first electrode and the second electrode and having a resistance value that continuously and reversibly changes; and a driving circuit that drives the nonvolatile resistive switching element. The nonvolatile resistive switching element has a property of transitioning to a low-resistance state when a first low-resistance-setting voltage pulse is applied once and transitioning to a high-resistance state when a first high-resistance-setting voltage pulse is applied once. The first low-resistance-setting voltage pulse applies a negative electric potential to the second electrode with respect to the first electrode. The high-resistance state has a resistance value higher than a resistance value in the low-resistance state. The first high-resistance-setting voltage pulse applying a positive electric potential to the second electrode with respect to the first electrode. The driving circuit, when it is determined that the resistance value of the nonvolatile resistive switching element is below a lower limit of a target resistance value, applies a second high-resistance-setting voltage pulse and the first low-resistance-setting voltage pulse following the second high-resistance-setting voltage pulse to the nonvolatile resistive switching element. The second high-resistance-setting voltage pulse has second energy greater than first energy corresponding to a single application of the first high-resistance-setting voltage pulse, and applies a positive electric potential to the second electrode with respect to the first electrode.

According to the above, the present disclosure has implemented a method for driving a semiconductor device and a semiconductor device which are capable of, for a nonvolatile resistive switching element, (i) as compared to conventional write methods, reducing variation in initially-written resistance values, fluctuation in readout resistance values, and retention degradation, and (ii) unlike the technique disclosed by PTL 1, changing, in an analog manner, the resistance value toward both higher- and lower-resistance states.

### Embodiment

Hereinafter, embodiments according to the present disclosure will be described in detail with reference to the drawings. Note that the embodiments described below each show a specific example of the present disclosure. The numerical values, shapes, materials, elements, the arrangement and connection of the elements, steps, orders of the steps, etc. presented in the embodiment below are mere examples, and are not intended to limit the present disclosure. Moreover, the drawings do not necessarily provide strictly accurate illustrations. Throughout the drawings, the same reference sign is given to substantially the same configuration, and redundant description is omitted or simplified. Furthermore, the term “connection” means an electrical connection, and includes not only the case where two circuit elements are directly connected but also the case where two circuit elements are indirectly connected with another circuit element interposed therebetween.

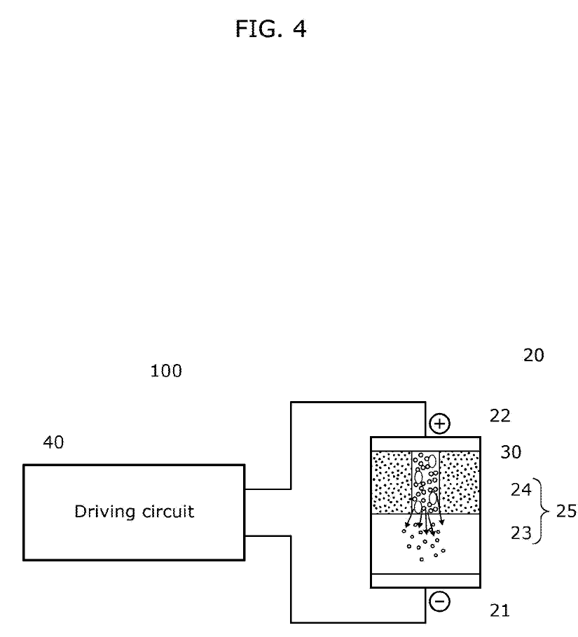

FIG. 4 is a block diagram illustrating a configuration of semiconductor device 100 according to the embodiment.

Semiconductor device 100 includes nonvolatile resistive switching element 20 and driving circuit 40 that drives nonvolatile resistive switching element 20, and is capable of reducing, for nonvolatile resistive switching element 20, variation in initially-written resistance values, fluctuation in readout resistance values, and retention degradation, and unlike the technique disclosed by PTL 1, changing, in an analog manner, the resistance value toward both higher- and lower-resistance states.

Nonvolatile resistive switching element 20 includes first electrode 21, second electrode 22, and resistance change layer 25 that is interposed between first electrode 21 and second electrode 22 and has the resistance value that continuously and reversibly changes. First electrode 21 is, for example, tantalum nitride (TaN) or the like. Second electrode 22 includes at least one of, for example, platinum (Pt), iridium (Ir), or palladium (Pd). In the present embodiment, resistance change layer 25 has a stacked structure that includes first metal oxide layer 23 including tantalum oxide (TaOₓ) or the like having a high oxygen deficiency, and second metal oxide layer 24 including tantalum pentoxide (Ta₂O₅) or the like having a small oxygen deficiency. In second metal oxide layer 24, filament 30 is formed. Filament 30 is a localized region through which current flows between first electrode 21 and second electrode 22 and whose shape varies depending on the resistance value of nonvolatile resistive switching element 20.

In a binary storage mode, this nonvolatile resistive switching element 20 has a property of transitioning to (i) a low-resistance state (also referred to as the “set state”) when a first low-resistance-setting voltage pulse that applies a negative electric potential to second electrode 22 with respect to first electrode 21 is applied once and (ii) a high-resistance state (also referred to as the “reset state”) having the resistance value higher than the resistance value in the low-resistance state when a first high-resistance-setting voltage pulse that applies a positive electric potential to second electrode 22 with respect to first electrode 21 is applied once.

Driving circuit 40 can drive nonvolatile resistive switching element 20 in both the binary storage mode and multi-level storage mode, and includes a write circuit for writing resistance values to nonvolatile resistive switching element 20, a sense amplifier for reading the resistance values from nonvolatile resistive switching element 20, memory that retains programs for controlling the foregoing circuit and amplifier, a processor that executes these programs, etc. In the multi-level storage mode, when the resistance value of nonvolatile resistive switching element 20 is below the lower limit of a target resistance value, driving circuit 40 applies, to nonvolatile resistive switching element 20, (i) a second high-resistance-setting voltage pulse that has second energy greater than first energy corresponding to a single application of the first high-resistance-setting voltage pulse, and applies a positive electric potential to second electrode 22 with respect to first electrode 21 and (ii) a first low-resistance-setting voltage pulse that follows the second high-resistance-setting voltage pulse.

More specifically, a method for driving nonvolatile resistive switching element 20 in the multivalued storage mode by driving circuit 40 includes: setting or obtaining the lower limit of a target resistance value of nonvolatile resistive switching element 20; measuring a resistance value of nonvolatile resistive switching element 20; determining whether the resistance value measured is below the lower limit of the target resistance value; and applying, when it is determined that the resistance value measured is below the lower limit of the target resistance value, a second high-resistance-setting voltage pulse and a first low-resistance-setting voltage pulse following the second high-resistance-setting voltage pulse to nonvolatile resistive switching element 20. The second high-resistance-setting voltage pulse has second energy greater than first energy corresponding to a single application of the first high-resistance-setting voltage pulse, and applies a positive electric potential to second electrode 22 with respect to first electrode 21.

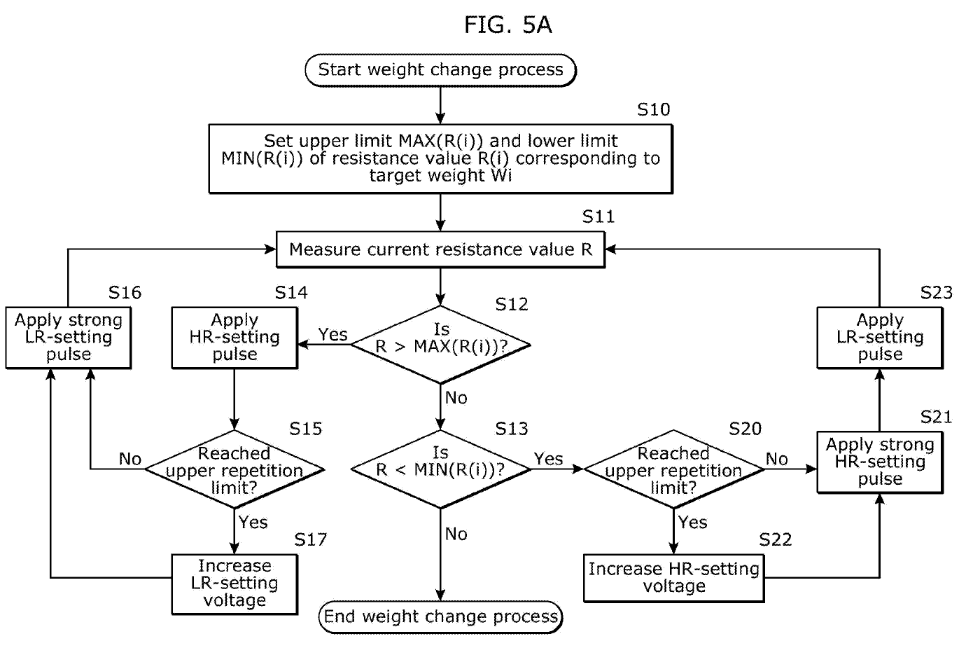

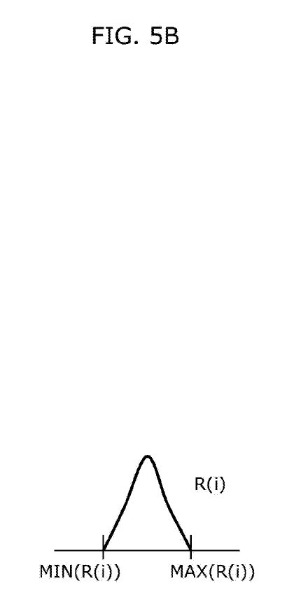

FIG. 5A is a flowchart illustrating operation performed by semiconductor device 100 (i.e., a method for driving semiconductor device 100) according to the embodiment. This flowchart shows operation performed when a resistance value is written to nonvolatile resistive switching element 20 as a weight taking an analog, continuous value used in neural networks and the like (i.e., in the multi-level storage mode).

In order to change weight Wi stored in nonvolatile resistive switching element 20, driving circuit 40 sets, in the first place, upper limit MAX(R(i)) and lower limit MIN(R(i)) of resistance value R(i) that corresponds to target weight Wi (setting step S10). FIG. 5B is a diagram illustrating an example of a distribution of resistance value R(i) corresponding to target weight Wi. Here, an example shows an ideal distribution of resistance value R(i) that corresponds to target weight Wi, where the maximum value and the minimum value are denoted as upper limit MAX(R(i)) and lower limit MIN(R(i)), respectively.

Referring again to FIG. 5A, in step S10, driving circuit 40, to be more specific, performs a predetermined calculation using target weight Wi obtained from external or internal memory and thereby sets upper limit MAX(R(i)) and lower limit MIN(R(i)) of resistance value R(i), for example. Instead of setting, driving circuit 40 may obtain upper limit MAX (R(i)) and lower limit MIN (R(i)) from the external or internal memory.

Next, driving circuit 40 measures the current resistance value R of nonvolatile resistive switching element 20 (measuring step S11), and determines whether resistance value R obtained by the measuring exceeds upper limit MAX(R(i)) (S12). Note that when a measurement circuit that measures resistance value R is externally provided, driving circuit 40 may obtain resistance value R from the externally provided measurement circuit.

When it is determined that resistance value R exceeds upper limit MAX R(i)) as the result of the determining in step S12 (Yes in S12), driving circuit 40 applies, in the first place, a high-resistance (HR)-setting pulse to nonvolatile resistive switching element 20 for reducing the resistance (S14). Here, an HR-setting pulse is a high-resistance-setting pulse in the binary storage mode. In other words, an HR-setting pulse is a first high-resistance-setting voltage pulse that applies a positive electric potential to second electrode 22 with respect to first electrode 21, to write one state (i.e., the reset state) in the binary storage mode.

Next, driving circuit 40 determines whether the total number of HR-setting pulses applied to date (S14) has reached a predetermined upper repetition limit (S15). When the total number has not reached the upper repetition limit (No in S15), driving circuit 40 applies a strong low-resistance (LR)-setting pulse (S16). Alternatively, when the total number has reached the upper repetition limit (Yes in S15), driving circuit 40 increases an LR-setting voltage (S17) to increase the likelihood of further reducing the resistance, and then applies a strong LR-setting pulse (S16).

Here, a strong LR-setting pulse is one example of a second low-resistance-setting voltage pulse having greater energy (specifically, a larger amplitude) than a single application of the first low-resistance-setting voltage pulse that applies a negative electric potential to second electrode 22 with respect to first electrode 21 to reduce the resistance in the binary storage mode, or in other words, to write the other state (i.e., the set state) in the binary storage mode. Moreover, “increase[ing] an LR-setting voltage” means increasing the amplitude of an LR‑setting pulse to a larger amplitude than the amplitude of the previous LR‑setting pulse.

When it is determined that resistance value R does not exceed upper limit MAX (R(i)) as the result of the determining in step S12 (No in S12), driving circuit 40 determines that a condition relating to upper limit MAX (R(i)) is satisfied, and then proceeds to determine whether resistance value R obtained by the measuring in step S11 is below lower limit MIN (R(i)) (determining step S13).

When it is determined that resistance value R is not below lower limit MIN (R(i)) as the result of the determining in step S13 (No in S13), driving circuit 40 determines that resistance value R is an appropriate value between lower limit MIN (R(i)) and upper limit MAX (R(i)) and ends the process of writing the resistance value to nonvolatile resistive switching element 20, or in other words, the weight change process.

Alternatively, when it is determined that resistance value R is below lower limit MIN (R(i)) as the result of the determining in step S13, driving circuit 40 then determines whether the total number of sets of a strong HR-setting pulse and an LR-setting pulse applied to date (S21 and S23) has reached a predetermined upper repetition limit (S20). When the total number has not reached the upper repetition limit (No in S20), driving circuit 40 applies a strong HR-setting pulse to nonvolatile resistive switching element 20 for increasing the resistance (S21) and applies an LR-setting pulse thereafter (S23). Alternatively, when the total number has reached the upper repetition limit (Yes in S20), driving circuit 40 increases an HR-setting voltage (changing step S22) to increase the likelihood of further increasing the resistance and then applies a strong HR-setting pulse to nonvolatile resistive switching element 20 (S21), and applies an LR-setting pulse thereafter (S23).

Here, a strong HR-setting pulse is one example of a second high-resistance-setting voltage pulse having greater energy (here, a larger amplitude) than a single application of the first high-resistance-setting voltage pulse that applies a positive electric potential to second electrode 22 with respect to first electrode 21 to increase the resistance in the binary storage mode, or in other words, to write one state (i.e., the reset state) in the binary storage mode. Moreover, “increase[ing] an HR-setting voltage” means increasing the amplitude of an HR‑setting pulse to a larger amplitude than the amplitude of the previous HR‑setting pulse. Note that a set of steps S21 and S23 corresponds to one specific example of the applying step of applying, to nonvolatile resistive switching element 20, (i) a second high-resistance-setting voltage pulse that has second energy greater than first energy corresponding to a single application of the first high-resistance-setting voltage pulse, and applies a positive electric potential to second electrode 22 with respect to first electrode 21 and (ii) a first low-resistance-setting voltage pulse that follows the second high-resistance-setting voltage pulse.

Note that driving circuit 40 stores and updates the total number of voltage pulses applied each time a voltage pulse is applied, and determines whether the total number of voltage pulses applied has reached the upper repetition limit based on the total number (S15 and S20).

In the flowchart shown in FIG. 5A, the high-resistance setting performed by at least steps S20 to S23 is a series of distinctive steps capable of, for a nonvolatile resistive switching element, (i) as compared to conventional high-resistance settings, reducing variation in initially-written resistance values, fluctuation in readout resistance values, and retention degradation and (ii) unlike the technique disclosed by PTL 1, changing, in an analog manner, the resistance value toward both higher- and lower-resistance states.

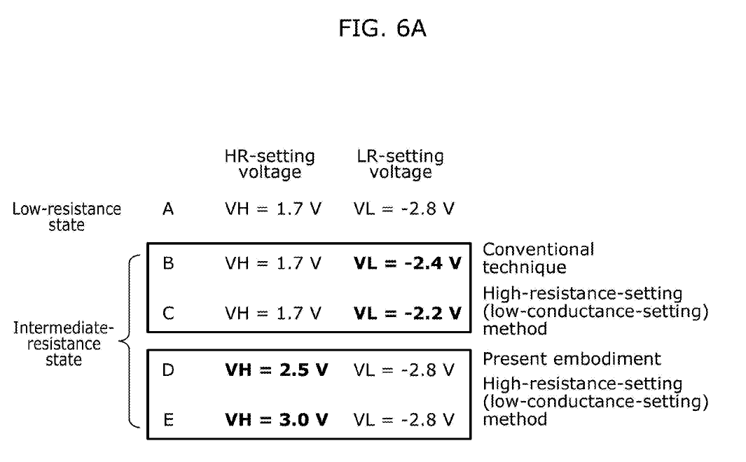

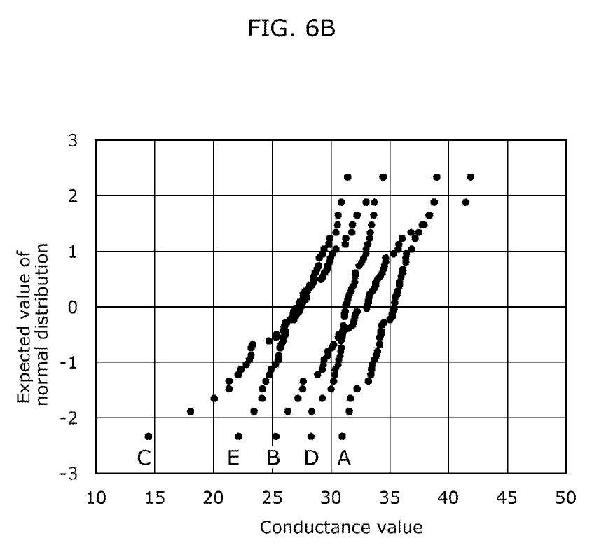

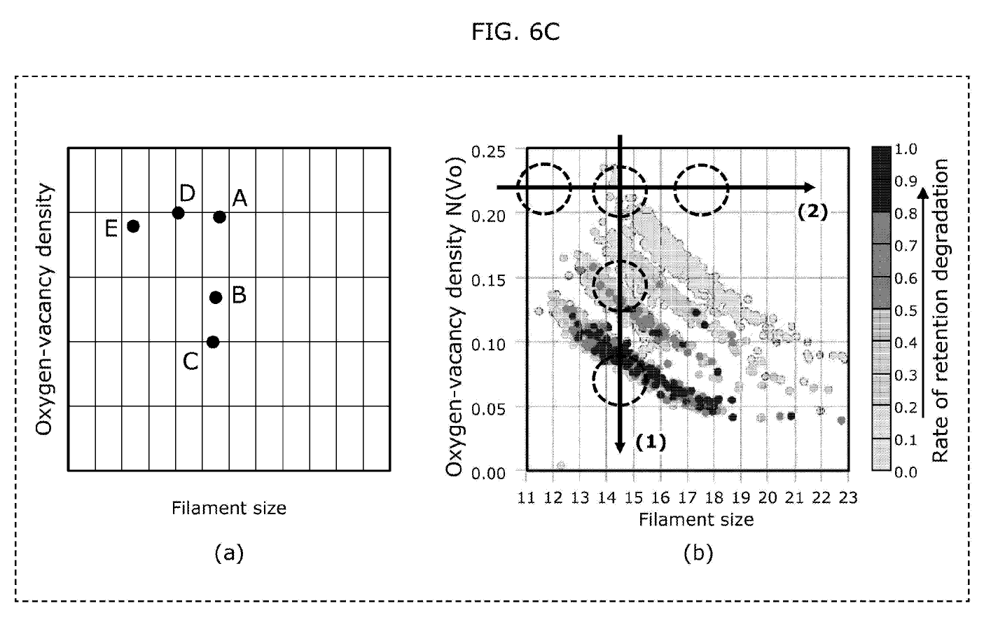

FIG. 6A is a diagram illustrating voltage conditions used in the experiment conducted in accordance with the flowchart shown in FIG. 5A, in which nonvolatile resistive switching element 20 is changed from a low-resistance state toward a higher-resistance state to achieve a plurality of resistance states, together with voltage conditions according to a conventional technique. The diagram shows an example of HR-setting pulse voltages (“HR-setting voltage” in FIG. 6A) and LR-setting pulse voltages (“LR-setting voltage” in FIG. 6A) used for writing: in the binary storage mode (case “A” (Low-resistance state) in FIG. 6A); two types of high-resistance settings (i.e., low-conductance settings) in the multivalued storage mode according to the conventional technique (cases “B” and “C” (Intermediate-resistance state) in FIG. 6A); and two types of high-resistance settings (i.e., low-conductance settings) in the multivalued storage mode according to the present embodiment (cases “D” and “E” (Intermediate-resistance state) in FIG. 6A).

As shown in the cases “B” and “C” in FIG. 6A, in the high-resistance setting in the intermediate-resistance state in the multivalued storage mode according to the conventional technique, voltage VH (1.7 V) of HR-setting pulses is the same as voltage VH (1.7 V) used for the high-resistance setting in the binary storage mode and voltages VL (−2.4 V and −2.2 V) of LR-setting pulses are weak LR-setting pulses having a smaller amplitude than the amplitude of voltage VL (−2.8 V) used for the low-resistance setting in the binary storage mode.

In contrast, as shown in cases “D” and “E” in FIG. 6A, in the high-resistance setting in the intermediate-resistance state in the multivalued storage mode according to the present embodiment, voltages VH (2.5 V and 3.0 V) of strong HR-setting pulses have a larger amplitude than the amplitude of voltage VH (1.7 V) used for the high-resistance setting in the binary storage mode and voltage VL (−2.8 V) of LR-setting pulses is the same as voltage VL (−2.8 V) used for reducing the resistance in the binary storage mode.

FIG. 6B is a diagram illustrating the distribution of conductance values (after application of the LR-setting voltages) obtained from a plurality of experiments of writing to nonvolatile resistive switching element 20 in cases A to E shown in FIG. 6A. The horizontal axis represents conductance values obtained from the writing in the experiments and the vertical axis represents the expected value of a normal distribution of each conductance within the distribution of all conductance values obtained for the case.

As can be seen from FIG. 6B, the distribution of conductance values obtained in cases D and E according to the present embodiment has a narrower horizontal width (i.e., variation in conductance values) in the distribution of conductance values, as compared to cases B and C according to the conventional technique.

FIG. 6C is a diagram illustrating results of analyzing filament properties using the results of experiments of cases A to E shown in FIG. 6A. The diagram shows the results of analyzing filament properties suitable for analog resistance values based on the results of experiments conducted for the filament properties and data retention properties of nonvolatile resistive switching element 20, employing the same technique as the technique for obtaining analysis results shown in FIG. 2B (see PTL: Japanese Unexamined Patent Application Publication No. 2014-207046). More specifically, as in FIG. 2B, in part (b) of FIG. 6C, the horizontal axis represents the filament size, the vertical axis represents oxygen-vacancy density in the filament, and the plot density denotes the data retention properties (lighter gradation indicating better data retention). Part (a) of FIG. 6C shows the center of a distribution in each of cases A to E shown in part (b) of FIG. 6C.

As shown by cases “B” and “C” in part (a) of FIG. 6C and their corresponding straight line (1) in part (b) of FIG. 6C, in the high-resistance setting in the multivalued storage mode according to the conventional technique, the oxygen-vacancy density within the filament is controlled while maintaining (in other words, fixing) the filament size, and thereby controlling analog resistance values to be written. In such a method, large conductance values, which can maintain high oxygen-defect densities, exhibit good data retention properties. Conversely, for small conductance values corresponding to low oxygen-vacancy densities, oxygen vacancies having poor data retention properties are used due to the low oxygen-vacancy densities, causing variation in resistance values.

Whereas, as shown by cases “D” and “E” in part (a) of FIG. 6C and their corresponding straight line (2) in part (b) of FIG. 6C, in the high-resistance setting in the multivalued storage mode according to the present embodiment, the filament size is controlled while maintaining (in other words, fixing) a high oxygen-vacancy density. As a result, filaments with superior data retention properties are formed, or in other words, variation in resistance values is reduced.

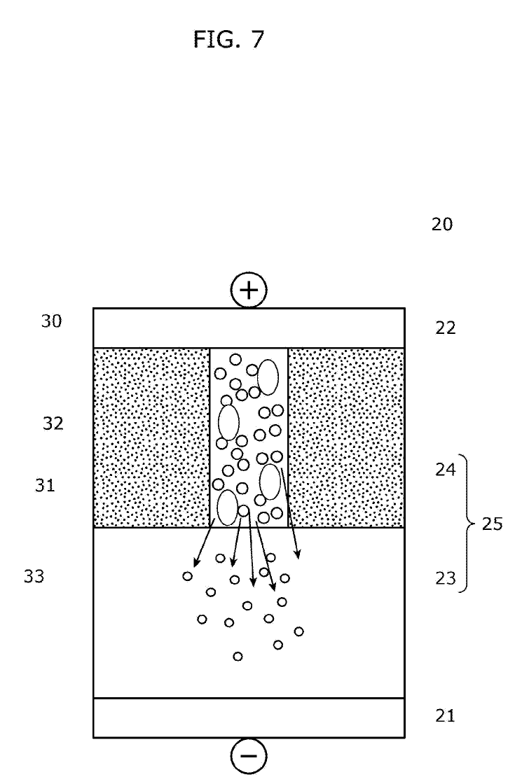

FIG. 7 is a diagram illustrating the state of a filament in an intermediate-resistance state after an LR-setting voltage is applied to nonvolatile resistive switching element 20 in the multivalued storage mode according to the embodiment. The structure of nonvolatile resistive switching element 20 shown in the diagram is basically the same as that of shown in FIG. 4, except that the inside of filament 30 and the like are shown in greater detail (i.e., as a filament-change model).

When, in the binary storage mode, a first low-resistance-setting voltage pulse applying a negative electric potential to second electrode 22 with respect to first electrode 21 is applied, oxygen within filament 30 moves into first metal oxide layer 23 as oxygen ions 33, thereby increasing oxygen vacancies 31 within filament 30. Consequently, the resistance value of filament 30 is reduced, and overall resistance value of nonvolatile resistive switching element 20 is reduced. Alternatively, when, in the binary storage mode, a first high-resistance-setting voltage pulse applying a positive electric potential to second electrode 22 with respect to first electrode 21 is applied, oxygen ions 33 within first metal oxide layer 23 move into filament 30 and bond to oxygen vacancies 31 within filament 30, thereby reducing oxygen vacancies 31 within filament 30. Consequently, the resistance value of filament 30 increases, and overall resistance value of nonvolatile resistive switching element 20 increases.

When it is determined that, in the multi-level storage mode, the resistance value of nonvolatile resistive switching element 20 is below the lower limit of the target resistance value, the following pulses are applied to nonvolatile resistive switching element 20 for the high-resistance setting: (i) a second high-resistance-setting voltage pulse that has second energy greater than first energy corresponding to a single application of the first high-resistance-setting voltage pulse, and applies a positive electric potential to second electrode 22 with respect to first electrode 21 and (ii) a first low-resistance-setting voltage pulse that follows the second high-resistance-setting voltage pulse (S21 and S23 in FIG. 5A).

Here, when a second high-resistance-setting voltage pulse having a large energy is applied to nonvolatile resistive switching element 20 (S21 in FIG. 5A), not only the oxygen ions within first metal oxide layer 23 move into filament 30 and bond to oxygen vacancies 31 within filament 30, but also, due to the large energy of the applied pulse, a large number of oxygen‑vacancy‑formation‑suppressed regions 32, in which formation of oxygen vacancies is difficult, are likely to be generated within filament 30. As a result, although the outer area of the filament as defined by its contour remains substantially unchanged, the effective filament area is reduced. In other words, the high-resistance setting can be achieved without significantly reducing the oxygen-vacancy density.

As described, according to the present embodiment, the effective filament area of a filament can be reversibly changed in an analog manner without significantly changing the oxygen-vacancy density within the filament (see FIG. 3). With this, a driving method capable of changing, in an analog manner, the resistance value toward both higher- and lower-resistance states can be implemented.

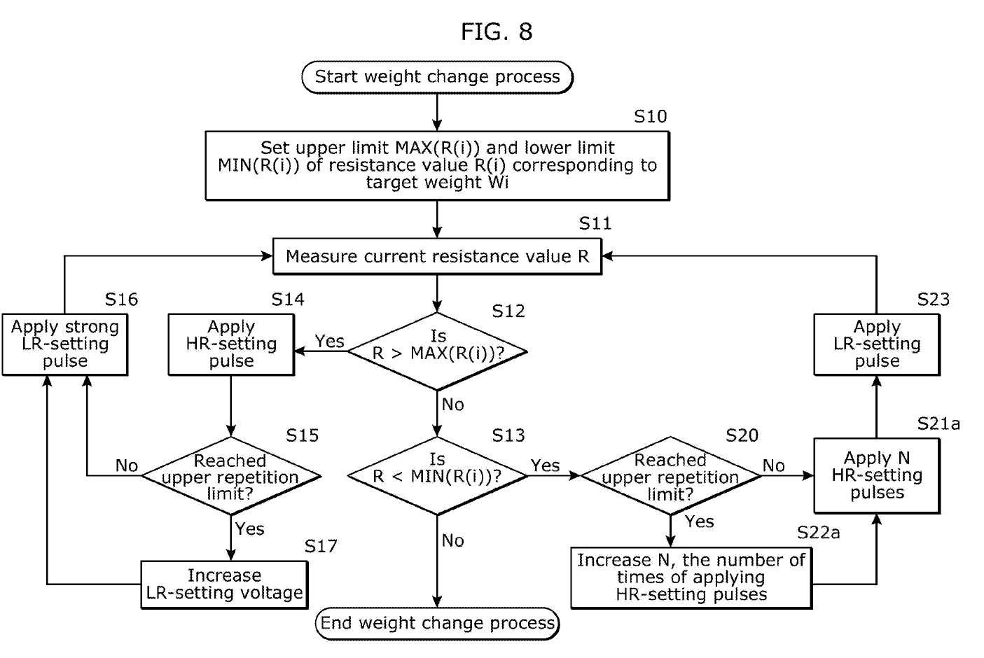

FIG. 8 is a flowchart illustrating operation performed by semiconductor device 100 (i.e., a method for driving semiconductor device 100) according to a variation of the embodiment. In the same manner as FIG. 5A, this flowchart shows operation performed when a resistance value is written to nonvolatile resistive switching element 20 as a weight taking an analog, continuous value used in neural networks and the like (i.e., in the multi-level storage mode). However, as compared to the flowchart shown in FIG. 5A, FIG. 8 is different from FIG. 5A in that step S21 and step S22 in FIG. 5A are replaced by step S21a and step S22a in FIG. 8, respectively. Hereinafter, differences from the flowchart shown in FIG. 5A will be described.

In the present variation, for the purpose of increasing the resistance of nonvolatile resistive switching element 20, N (≥ 2) HR-setting pulses are consecutively applied (S21a) instead of applying one strong HR-setting pulse as in FIG. 5A (S21). Here, a single HR-setting pulse is a third high-resistance-setting voltage pulse that applies a positive electric potential to second electrode 22 with respect to first electrode 21, and may be, for example, a high-resistance-setting pulse (i.e., a first high-resistance-setting voltage pulse) in the binary storage mode, a strong HR-setting pulse (i.e., a second high-resistance-setting voltage pulse) according to the above-described embodiment, or a high-resistance-setting pulse having an optional amplitude different from the amplitudes of any of the above pulses. In short, provided that a condition, in which the energy of N applied third high-resistance-setting voltage pulses is greater than the energy of a single application of the first high-resistance-setting voltage pulse, is satisfied, N may be any value greater than or equal to two, and the amplitude of each third high-resistance-setting voltage pulse may be any voltage.

In addition, in the present variation, when it is determined that the total number of sets of N HR-setting pulses (S21a) and an LR-setting pulse (S23) applied to date has reached the upper repetition limit (Yes in S20), driving circuit 40 increases N, the number of times the HR-setting pulses are applied (changing step S22a), to increase the likelihood of further increasing the resistance. Then, driving circuit 40 consecutively applies N HR-setting pulses to nonvolatile resistive switching element 20 (S21a), and applies an LR-setting pulse thereafter (S23). Note that the set of steps S21a and S23 corresponds to one specific example of the applying step of applying, to nonvolatile resistive switching element 20, (i) a second high-resistance-setting voltage pulse that has second energy greater than first energy corresponding to a single application of the first high-resistance-setting voltage pulse, and applies a positive electric potential to second electrode 22 with respect to first electrode 21 and (ii) a first low-resistance-setting voltage pulse that follows the second high-resistance-setting voltage pulse.

Even with such high‑resistance setting, since a second high‑resistance‑setting voltage pulse having second energy, which is a large energy, is applied to nonvolatile resistive switching element 20 (S21a in FIG. 8), a large number of oxygen‑vacancy‑formation‑suppressed regions 32 are formed within filament 30 due to the large energy of the applied pulses. As a result, although the outer area of the filament as defined by its contour remains substantially unchanged, the effective filament area is reduced. In other words, the high-resistance setting can be achieved without significantly reducing the oxygen-vacancy density, and the same advantageous effects as those of the driving method according to the embodiment can be produced.

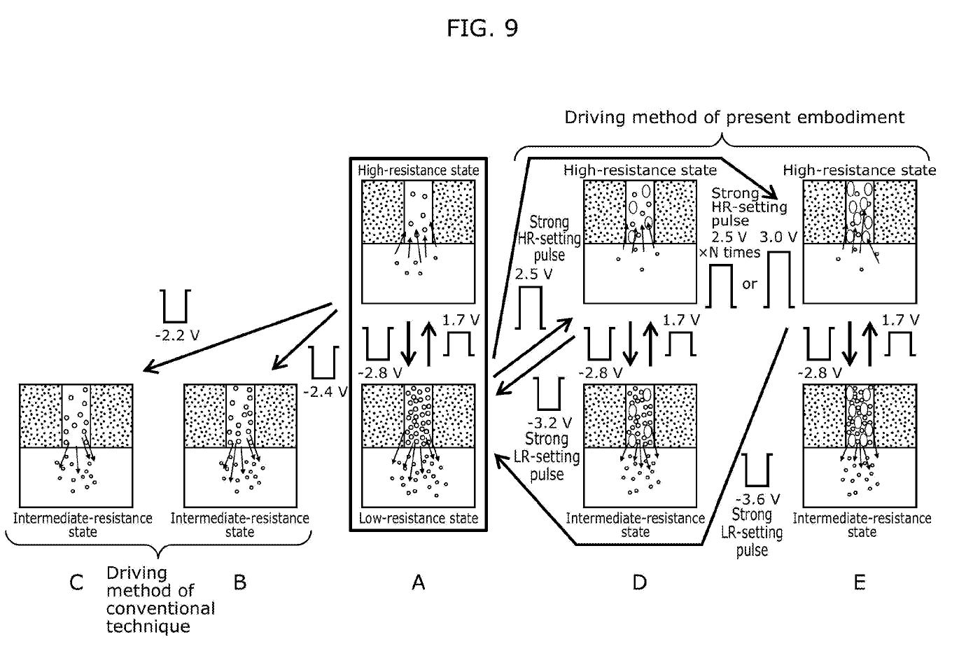

FIG. 9 is a diagram illustrating a filament-state change model of a filament in nonvolatile resistive switching element 20 for the driving methods according to the embodiment and the conventional technique. Case “A” showing a low-resistance state and cases “B” to “E” showing intermediate-resistance states correspond to cases “A” to “E” in FIG. 6A. However, for the transition from the low-resistance state in case A to the intermediate-resistance state in case E shown in the present diagram, the diagram shows not only the example of a strong HR-setting pulse (a strong HR-setting pulse of “3.0 V”) corresponding to case E in FIG. 6A, but also the example of N HR-setting pulses (a strong HR-setting pulse of “2.5 V × N”) according to the variation in step S21a of FIG. 8.

As shown by the filament-change model in case “D” in FIG. 9, both (i) the high-resistance state obtained by the application of a strong HR-setting pulse of 2.5 V to nonvolatile resistive switching element 20 in the low-resistance state and (ii) the intermediate-resistance state obtained by the application of an LR-setting pulse of −2.8 V following the strong HR-setting pulse exhibit substantially unchanged outer filament area as defined by its contour, while the effective filament area is changed.

Likewise, for case “E” in FIG. 9, both (i) the high-resistance state obtained either by the application of a strong HR-setting pulse of 3.0 V which is a stronger pulse than the pulse in case “D” or by the application of a plurality of (N) strong HR-setting pulses of 2.5 V each of which is the same as the pulse in case “D” and (ii) the intermediate-resistance state obtained by the application of an LR-setting pulse of −2.8 V following the strong HR-setting pulse or the N strong HR-setting pulses show that, as compared to case “D,” an increase in the number of oxygen‑vacancy‑formation‑suppressed regions 32 within filament 30. However, as in case “D,” the outer area of the filament as defined by its contour remains substantially unchanged, while the effective filament area is changed.

Moreover, as illustrated in the transition portion from the high-resistance state in case “D” to the low-resistance state in case “A” in the diagram, the return transition from case “D” to case “A” is achievable by the application of a strong LR-setting pulse of −3.2 V to nonvolatile resistive switching element 20.

Likewise, as illustrated in the transition portion from the high-resistance state in case “E” to the low-resistance state in case “A” in the diagram, the return transition from case “E” to case “A” is achievable by the application of a strong LR-setting pulse of −3.6 V to nonvolatile resistive switching element 20.

From the above, the use of the strong HR-setting pulses and the strong LR-setting pulses enables reversible transitions between case “A” and case “D” and between case “A” and case “E.”

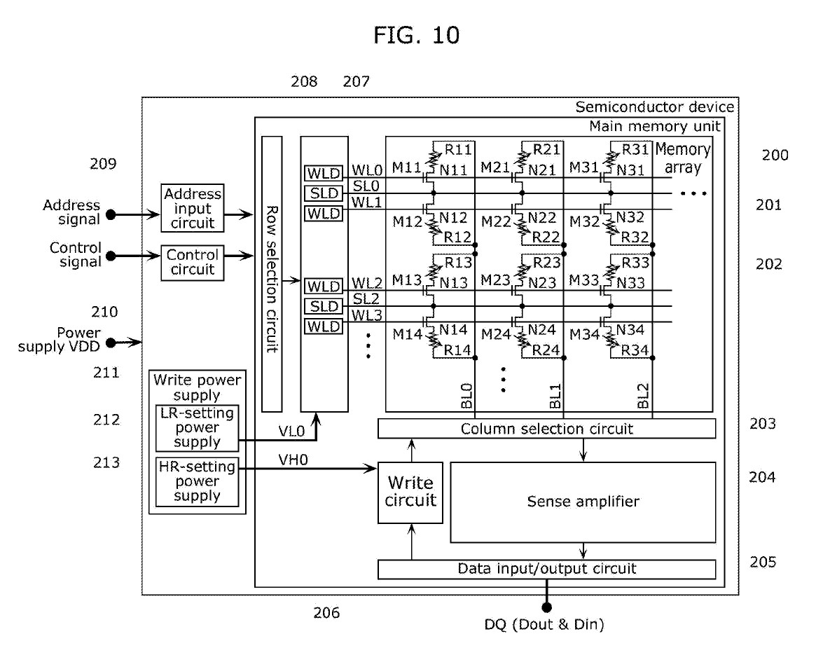

FIG. 10 is a block diagram illustrating a detailed configuration of semiconductor device 200 according to the embodiment.

Semiconductor device 200 corresponds to a specific example of semiconductor device 100 illustrated in FIG. 4, and includes main memory unit 201 above a semiconductor substrate (not illustrated). Main memory unit 201 includes: memory array 202 including two-dimensionally arranged one transistor, one resistor (1T1R) memory cells M11, M12, … including nonvolatile resistive switching element 20 shown in FIG. 4; row selection circuit 208; row driver 207 including word line drivers WLD and source line drivers SLD; column selection circuit 203; write circuit 206 for forming and data writing; sense amplifier 204 detecting an amount of current that flows through a selected bit line and determining a high-resistance state and a low-resistance state as data “0” and data “1,” respectively; and data input/output circuit 205 that performs input/output processing on input/output data DQ via terminal DQ.

Semiconductor device 200 further includes, as write power supply 211, high-resistance (HR)-setting power supply 213 and low-resistance (LR)-setting power supply 212. Semiconductor device 200 also includes address input circuit 209 that receives externally input address signals, and control circuit 210 that controls operation performed by main memory unit 201 based on externally input control signals. Note that driving circuit 40 shown in FIG. 4 corresponds to the peripheral circuits excluding memory array 202 in FIG. 10.

Memory array 202 includes, above the semiconductor substrate: a plurality of word lines WL0, WL1, WL2, WL3, … and a plurality of bit lines BL0, BL1, BL2, … which are arranged to mutually intersect with one another; a plurality of N-type metal oxide semiconductor (NMOS) transistors N11, N12, N13, N14, …, N21, N22, N23, N24, …, N31, N32, N33, N34, … (hereinafter, referred to as “transistors N11, N12, …”) provided at corresponding intersection points at which the aforementioned word lines WL0, WL1, WL2, WL3, … and bit lines BL0, BL1, BL2 intersect; and a plurality of nonvolatile resistive switching elements R11, R12, R13, R14, …, R21, R22, R23, R24, …, R31, R32, R33, R34, … (hereinafter, referred to as “nonvolatile resistive switching elements R11, R12, …) connected one-to-one in series with transistors N11, N12, …, and the plurality of transistors and the plurality of nonvolatile resistive switching elements, paired one-to-one, form memory cells M11, M12, M13, M14, …, M21, M22, M23, M24, …, M31, M32, M33, M34, … (hereinafter, referred to as “memory cells M11, M12, …”).

As illustrated in FIG. 10, the gates of transistors N11, N21, N31, … are connected to word line WL0, the gates of transistors N12, N22, N32, … are connected to word line WL1, the gates of transistors N13, N23, N33, … are connected to word line WL2, and the gates of transistors N14, N24, N34, … are connected to word line WL3.

Moreover, transistors N11, N21, N31, … and transistors N12, N22, N32, … are commonly connected to source line SL0, and transistors N13, N23, N33, … and transistors N14, N24, N34, … are commonly connected to source line SL2. In other words, source lines SL0, SL2, … are provided parallel to word lines WL0, WL1, WL2, WL3, … and are arranged to intersect with (in the present embodiment, in the vertical direction) bit lines BL0, BL1, BL2, …. Note that although the source lines are provided parallel to the word lines in the above-described configuration example, the source lines may be provided parallel to the bit lines. In addition, although the source lines are configured to apply a common electric potential to the transistors connected as plate lines, a source line selection circuit/driver configured in the same manner as the row selection circuit/driver may be provided. In this case, the selected source line and the unselected source lines may be driven at different voltages (including polarities).

Furthermore, nonvolatile resistive switching elements R11, R12, R13, R14, … are connected to bit line BL0, nonvolatile resistive switching elements R21, R22, R23, R24, … are connected to bit line BL1, and nonvolatile resistive switching elements R31, R32, R33, R34, … are connected to bit line BL2. As described, memory array 202 according to the embodiment takes the configuration in which nonvolatile resistive switching elements R11, R21, R31, … are directly connected to corresponding bit lines BL0, BL1, BL2, …, not via NMOS transistors N11, N21, N31, ….

Control circuit 210 is a processor or the like provided with programs to perform control in both the binary storage mode and the multivalued storage mode. In a data writing cycle, control circuit 210 outputs a write signal instructing an application of a write voltage to write circuit 206 in accordance with input data Din input to data input/output circuit 205. Alternatively, in a data reading cycle, control circuit 210 outputs a read signal instructing a read operation to sense amplifier 204. Moreover, in the multivalued storage mode, control circuit 210 performs control steps in accordance with the flowcharts shown in FIGS. 5A and 8.

Row selection circuit 208 receives a row address signal output from address input circuit 209, selects, in accordance with the row address signal, a word line driver WLD corresponding to any one of the plurality of word lines WL0, WL1, WL2, WL3, … in row driver 207, and applies a predetermined voltage to the selected word line.

Likewise, row selection circuit 208 receives a row address signal output from address input circuit 209, selects, in accordance with the row address signal, a source line driver SLD corresponding to any one of the plurality of source lines SL0, SL2, … in row driver 207, and applies a predetermined voltage to the selected source line.

When write circuit 206 receives a write signal output from control circuit 210, write circuit 206 applies a write voltage to a bit line selected by column selection circuit 203.

Write power supply 211 includes LR-setting power supply 212 for the low-resistance setting (i.e., for LR-setting pulses and strong LR-setting pulses) and HR-setting power supply 213 for the high-resistance setting (i.e., for HR-setting pulses and strong HR-setting pulses). Output VL0 of LR-setting power supply 212 is input to row driver 207 and output VH0 of HR-setting power supply 213 is input to write circuit 206.

According to semiconductor device 200 configured as above implements a single-chip semiconductor device that controls a nonvolatile resistive switching element selected from among a plurality of two-dimensionally arranged nonvolatile resistive switching elements 20 in the multivalued storage mode in accordance with the flowcharts shown in FIGS. 5A and 8.

As has been described above, a method for driving semiconductor device 100 according to the present embodiment and the variation is a method for driving semiconductor device 100 including nonvolatile resistive switching element 20. Semiconductor device 100 applies voltage pulses to nonvolatile resistive switching element 20 to continuously and reversibly change a resistance value of nonvolatile resistive switching element 20. Nonvolatile resistive switching element 20 includes: first electrode 21; second electrode 22; and resistance change layer 25 interposed between first electrode 21 and second electrode 22 and having a resistance value that continuously changes. Nonvolatile resistive switching element 20 has a property of transitioning to a low-resistance state when a first low-resistance-setting voltage pulse is applied once and transitioning to a high-resistance state when a first high-resistance-setting voltage pulse is applied once. The first low-resistance-setting voltage pulse applies a negative electric potential to second electrode 22 with respect to first electrode 21. The high-resistance state has a resistance value higher than a resistance value in the low-resistance state. The first high-resistance-setting voltage pulse applies a positive electric potential to second electrode 22 with respect to first electrode 21. The method for driving semiconductor device 100 includes, for example: setting step S10 of setting a lower limit of a target resistance value of nonvolatile resistive switching element 20; measuring step S11 of measuring the resistance value of nonvolatile resistive switching element 20; determining step S13 of determining whether the resistance value measured is below the lower limit of the target resistance value; and an applying step (a set of steps S21 and S23) of applying, when it is determined that the resistance value measured is below the lower limit of the target resistance value, a second high-resistance-setting voltage pulse and the first low-resistance-setting voltage pulse following the second high-resistance-setting voltage pulse to nonvolatile resistive switching element 20. The second high-resistance-setting voltage pulse has second energy greater than first energy corresponding to a single application of the first high-resistance-setting voltage pulse, and applies a positive electric potential to second electrode 22 with respect to first electrode 21.

With this, when nonvolatile resistive switching element 20 is changed to an intermediate-resistance state between a high-resistance state and a low-resistance state in an analog manner, the following pulses are applied to nonvolatile resistive switching element 20: (i) a second high-resistance-setting voltage pulse that has second energy greater than first energy corresponding to a single application of a first high-resistance-setting voltage pulse, and applies a positive electric potential to second electrode 22 with respect to first electrode 21 and (ii) a first low-resistance-setting voltage pulse that follows the second high-resistance-setting voltage pulse. As a result, the effective filament area of a filament in nonvolatile resistive switching element 20 can be reversibly changed in an analog manner without significantly changing the oxygen-vacancy density within the filament. Accordingly, it is possible to implement a method for driving a semiconductor device that is capable of, for a nonvolatile resistive switching element, (i) as compared to conventional write methods, reducing variation in initially-written resistance values, fluctuation in readout resistance values, and retention degradation, and (ii) changing, in an analog manner, the resistance value toward both higher- and lower-resistance states.

Here, measuring step S11, determining step S13, the applying step (a set of applying steps S21 and S23), etc., may be repeatedly performed until it is determined, in determining step S13, that the resistance value measured is not below the lower limit of the target resistance value. With this, when the resistance value does not reach or exceed the lower limit of the target resistance value by performing a single set of applying steps S21 and S23, etc., repeatedly performing the set of applying steps S21 and S23, etc., increases the likelihood of achieving a resistance value that reaches or exceeds the lower limit of the target resistance value.

Moreover, a step such as changing step S22 of changing a value of the second energy to a greater value may further be included, when (i) the applying step (the set of applying steps S21 and S23), etc., are repeatedly performed a predetermined number of times and (ii) it is determined, in determining step S13, that the resistance value measured is below the lower limit of the target resistance value. With this, the set of applying steps S21 and S23, etc., are repeatedly performed with an increase in the applied energy, thereby further increasing the likelihood of achieving the resistance value that reaches or exceeds the lower limit of the target resistance value.

In addition, the second high-resistance-setting voltage pulse may have an amplitude larger than an amplitude of the first high-resistance-setting voltage pulse. With an increase in the amplitude of an applied voltage pulse, a second high-resistance-setting voltage pulse can be achieved.

Furthermore, measuring step S11, determining step S13, and the applying step (the set of applying steps S21 and S23) may be repeatedly performed until it is determined, in determining step S13, that the resistance value measured is not below the lower limit of the target resistance value, and the method for driving the semiconductor device may further include changing step S22 of changing an amplitude of the second high-resistance-setting voltage pulse to a larger amplitude, when (i) the applying step (the set of applying steps S21 and S23) is repeatedly performed a predetermined number of times and (ii) it is determined, in determining step S13, that the resistance value measured is below the lower limit of the target resistance value. With this, when the resistance value does not reach or exceed the lower limit of the target resistance value by performing a single set of applying steps S21 and S23, the set of applying steps S21 and S23 is repeatedly performed with an increase in the applied amplitude. This increases the likelihood of achieving a resistance value that reaches or exceeds the lower limit of the target resistance value.

Moreover, the second high-resistance-setting voltage pulse may include consecutive third high-resistance-setting voltage pulses each applying a positive electric potential to second electrode 22 with respect to first electrode 21. With a plurality of applied voltage pulses, a second high-resistance-setting voltage pulse can be achieved.

In addition, measuring step S11, determining step S13, and the applying step (the set of applying steps S21a and S23) may be repeatedly performed until it is determined, in determining step S13, that the resistance value measured is not below the lower limit of the target resistance value, and the method for driving the semiconductor device may further include changing step S22a of changing the total number of the third high-resistance-setting voltage pulses included in the second high-resistance-setting voltage pulse to a greater number, when (i) the applying step (the set of applying steps S21a and S23) is repeatedly performed a predetermined number of times and (ii) it is determined, in determining step S13, that the resistance value measured is below the lower limit of the target resistance value. With this, when the resistance value does not reach or exceed the lower limit of the target resistance value by performing a single set of applying steps S21a and S23, the set of applying steps S21a and S23 is repeatedly performed with an increase in the total number of applied voltage pulses. This increases the likelihood of achieving a resistance value that reaches or exceeds the lower limit of the target resistance value.

Furthermore, resistance change layer 25 may include filament 30 that is a localized region through which current flows between first electrode 21 and second electrode 22 and whose shape varies depending on the resistance value of nonvolatile resistive switching element 20, and an effective filament area of filament 30 in a plan view of resistance change layer 25 may change by the applying step (the set of applying steps S21 and S23), etc. With this, the effective filament area of a filament in nonvolatile resistive switching element 20 can be reversibly changed in an analog manner without significantly changing the oxygen-vacancy density within the filament.

Moreover, semiconductor device 100 according to the embodiment and the variation includes: nonvolatile resistive switching element 20 that includes first electrode 21, second electrode 22, and resistance change layer 25 interposed between first electrode 21 and second electrode 22 and having a resistance value that continuously and reversibly changes; and driving circuit 40 that drives nonvolatile resistive switching element 20. Nonvolatile resistive switching element 20 has a property of transitioning to a low-resistance state when a first low-resistance-setting voltage pulse is applied once and transitioning to a high-resistance state when a first high-resistance-setting voltage pulse is applied once. The first low-resistance-setting voltage pulse applies a negative electric potential to second electrode 22 with respect to first electrode 21. The high-resistance state has a resistance value higher than a resistance value in the low-resistance state. The first high-resistance-setting voltage pulse applies a positive electric potential to second electrode 22 with respect to first electrode 21. Driving circuit 40, when it is determined that the resistance value of nonvolatile resistive switching element 20 is below a lower limit of a target resistance value, applies a second high-resistance-setting voltage pulse and the first low-resistance-setting voltage pulse following the second high-resistance-setting voltage pulse to nonvolatile resistive switching element 20. The second high-resistance-setting voltage pulse has second energy greater than first energy corresponding to a single application of the first high-resistance-setting voltage pulse, and applies a positive electric potential to second electrode 22 with respect to first electrode 21.

With this, when nonvolatile resistive switching element 20 is changed to an intermediate-resistance state between a high-resistance state and a low-resistance state in an analog manner, driving circuit 40 applies the following pulses to nonvolatile resistive switching element 20: (i) a second high-resistance-setting voltage pulse that has second energy greater than first energy corresponding to a single application of a first high-resistance-setting voltage pulse, and applies a positive electric potential to second electrode 22 with respect to first electrode 21 and (ii) a first low-resistance-setting voltage pulse that follows the second high-resistance-setting voltage pulse. As a result, the effective filament area of a filament in nonvolatile resistive switching element 20 can be reversibly changed in an analog manner without significantly changing the oxygen-vacancy density within the filament. Therefore, it is possible to implement a semiconductor device that is capable of, for a nonvolatile resistive switching element, (i) as compared to conventional write methods, reducing variation in initially-written resistance values, fluctuation in readout resistance values, and retention degradation, and (ii) unlike the technique disclosed by PTL 1, changing, in an analog manner, the resistance value toward both higher- and lower-resistance states.

Hereinbefore, the method for driving a semiconductor device and the semiconductor device according to the present disclosure have been described based on the embodiment and the variation, but the present disclosure is not limited by the embodiment and the variation. The scope of the present disclosure encompasses embodiments as a result of making, to the present embodiments and variations, various modifications that may be conceived by those skilled in the art, and different embodiments achieved by combining some elements in the embodiments and variations, as long as the resultant embodiments do not depart from the spirit of the present disclosure.

For example, in the above-described embodiment, when increasing the resistance of nonvolatile resistive switching element 20, one strong HR-setting pulse and one LR-setting pulse are applied to nonvolatile resistive switching element 20 in a single cycle (S21 and S23 in FIG. 5A). However, the number of strong HR-setting pulses and LR-setting pulses is not limited to one each; at least one of the strong HR-setting pulse and the LR-setting pulse may be applied a plurality of times.

Moreover, in an increase in the resistance of nonvolatile resistive switching element 20, when the number of times of application has reached the upper limit, an HR-setting voltage is increased (S22) in the above-described embodiment, whereas the number of times of application N is increased (S22a) in the variation; however, the increase is not limited to either measure alone, and both an increase in the HR-setting voltage and an increase in the number of times of application N may be employed.

In addition, in the above-described embodiment, resistance change layer 25 of nonvolatile resistive switching element 20 has a stacked structure including first metal oxide layer 23 and second metal oxide layer 24; however, the structure is not limited to such structure and resistance change layer 25 may include a single layer. Furthermore, resistance change layer 25 is not limited to include tantalum oxide, and may include, for example, transition metal oxides, such as nickel oxide (NiO), titanium dioxide (TiO₂), hafnium dioxide (HfO₂), or zirconium dioxide (ZrO₂), or an aluminum oxide.

Moreover, the method for driving a semiconductor device according to the above-described embodiment and the variation may be implemented as a program including steps included in the driving method or as a computer-readable recording medium on which the program is recorded, such as a DVD.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The present disclosure relates to a semiconductor device capable of, for a nonvolatile resistive switching element, changing the resistance value toward both higher- and lower-resistance states in an analog manner. Such a semiconductor device can, of course, be used for multivalued recording in nonvolatile memory, and can also be used in machine learning models for neural networks and the like, not only for inference purposes but also for training purposes in which weight coefficients are changed in an analog manner.

1. A method for driving a semiconductor device including a nonvolatile resistive switching element, the semiconductor device applying voltage pulses to the nonvolatile resistive switching element to continuously and reversibly change a resistance value of the nonvolatile resistive switching element,
the nonvolatile resistive switching element including: a first electrode; a second electrode; and a resistance change layer interposed between the first electrode and the second electrode and having a resistance value that continuously changes,
the nonvolatile resistive switching element having a property of transitioning to a low-resistance state when a first low-resistance-setting voltage pulse is applied once and transitioning to a high-resistance state when a first high-resistance-setting voltage pulse is applied once, the first low-resistance-setting voltage pulse applying a negative electric potential to the second electrode with respect to the first electrode, the high-resistance state having a resistance value higher than a resistance value in the low-resistance state, the first high-resistance-setting voltage pulse applying a positive electric potential to the second electrode with respect to the first electrode,
the method for driving the semiconductor device comprising:
setting a lower limit of a target resistance value of the nonvolatile resistive switching element;
measuring the resistance value of the nonvolatile resistive switching element;
determining whether the resistance value measured is below the lower limit of the target resistance value; and
applying, when it is determined that the resistance value measured is below the lower limit of the target resistance value, a second high-resistance-setting voltage pulse and the first low-resistance-setting voltage pulse following the second high-resistance-setting voltage pulse to the nonvolatile resistive switching element, the second high-resistance-setting voltage pulse having second energy greater than first energy corresponding to a single application of the first high-resistance-setting voltage pulse, and applying a positive electric potential to the second electrode with respect to the first electrode.

2. The method for driving the semiconductor device according to claim 1, wherein
the measuring, the determining, and the applying are repeatedly performed until it is determined, in the determining, that the resistance value measured is not below the lower limit of the target resistance value.

3. The method for driving the semiconductor device according to claim 2, further comprising:
changing a value of the second energy to a greater value, when (i) the applying is repeatedly performed a predetermined number of times and (ii) it is determined, in the determining, that the resistance value measured is below the lower limit of the target resistance value.

4. The method for driving the semiconductor device according to claim 1, wherein
the second high-resistance-setting voltage pulse has an amplitude larger than an amplitude of the first high-resistance-setting voltage pulse.

5. The method for driving the semiconductor device according to claim 4, wherein
the measuring, the determining, and the applying are repeatedly performed until it is determined, in the determining, that the resistance value measured is not below the lower limit of the target resistance value, and
the method for driving the semiconductor device further comprises:
changing the amplitude of the second high-resistance-setting voltage pulse to a larger amplitude, when (i) the applying is repeatedly performed a predetermined number of times and (ii) it is determined, in the determining, that the resistance value measured is below the lower limit of the target resistance value.

6. The method for driving the semiconductor device according to claim 1, wherein
the second high-resistance-setting voltage pulse includes consecutive third high-resistance-setting voltage pulses each applying a positive electric potential to the second electrode with respect to the first electrode.

7. The method for driving the semiconductor device according to claim 6, wherein
the measuring, the determining, and the applying are repeatedly performed until it is determined, in the determining, that the resistance value measured is not below the lower limit of the target resistance value, and
the method for driving the semiconductor device further comprises:
changing a total number of the third high-resistance-setting voltage pulses included in the second high-resistance-setting voltage pulse to a greater number, when (i) the applying is repeatedly performed a predetermined number of times and (ii) it is determined, in the determining, that the resistance value measured is below the lower limit of the target resistance value.

8. The method for driving the semiconductor device according to claim 1, wherein
the resistance change layer includes a filament that is a localized region through which current flows between the first electrode and the second electrode and whose shape varies depending on the resistance value of the nonvolatile resistive switching element, and
an effective filament area of the filament in a plan view of the resistance change layer changes by the applying.

9. A semiconductor device comprising:
a nonvolatile resistive switching element that includes: a first electrode; a second electrode; and a resistance change layer interposed between the first electrode and the second electrode and having a resistance value that continuously and reversibly changes; and
a driving circuit that drives the nonvolatile resistive switching element, wherein
the nonvolatile resistive switching element has a property of transitioning to a low-resistance state when a first low-resistance-setting voltage pulse is applied once and transitioning to a high-resistance state when a first high-resistance-setting voltage pulse is applied once, the first low-resistance-setting voltage pulse applying a negative electric potential to the second electrode with respect to the first electrode, the high-resistance state having a resistance value higher than a resistance value in the low-resistance state, the first high-resistance-setting voltage pulse applying a positive electric potential to the second electrode with respect to the first electrode, and
the driving circuit, when it is determined that the resistance value of the nonvolatile resistive switching element is below a lower limit of a target resistance value, applies a second high-resistance-setting voltage pulse and the first low-resistance-setting voltage pulse following the second high-resistance-setting voltage pulse to the nonvolatile resistive switching element, the second high-resistance-setting voltage pulse having second energy greater than first energy corresponding to a single application of the first high-resistance-setting voltage pulse, and applying a positive electric potential to the second electrode with respect to the first electrode.
